(19) United States
(12) Patent Application Publication
(10) Pub. No.: US 2026/0128569 A1
(43) Pub. Date: May 7, 2026

(54) VERTICAL-CAVITY SURFACE-EMITTING SEMICONDUCTOR LASER AND METHOD FOR PRODUCING A SEMICONDUCTOR LASER OF THIS TYPE

(71) Applicant: TRUMPF PHOTONIC COMPONENTS GMBH, Ulm (DE)

(72) Inventor: Roman KOERNER, Lonsee (DE)

(21) Appl. No.: 19/434,012

(22) Filed: Dec. 29, 2025

Related U.S. Application Data
(63) Continuation of application No. PCT/EP2024/068778, filed on Jul. 3, 2024.

(30) Foreign Application Priority Data
Jul. 6, 2023 (DE) 10 2023 117 883.0

(51) Int. Cl. H01S 5/183

(52) U.S. Cl. CPC H01S 5/1835; H01S 5/18311

(57) ABSTRACT

A vertical-cavity surface-emitting semiconductor laser includes a semiconductor multi-layer structure in which a trench is formed, the trench running in a peripheral direction around a longitudinal center axis which runs perpendicularly to the semiconductor multi-layer structure and forming a mesa from the semiconductor multi-layer structure. The mesa contains a layer which is oxidized from an outer periphery of the mesa perpendicularly to the longitudinal center axis up to a predefined oxidation distance in order to form in the mesa an aperture for narrowing down an electrical and/or optical path. The trench has, in the peripheral direction around the longitudinal center axis, a plurality of portions in which the trench is closer to the longitudinal center axis than in other portions of the trench. The mesa has an inner mesa region and a plurality of support structures which surround the inner mesa region.

### CROSS REFERENCE TO RELATED APPLICATIONS

This application is a continuation of International Application No. PCT/EP2024/068778 (WO 2025/008426 A1), filed on July 3, 2024, and claims benefit to German Patent Application No. DE 102023117 883.0, filed on July 6, 2023. The aforementioned applications are hereby incorporated by reference herein.

### FIELD

The invention relates to a vertical-cavity surface-emitting semiconductor laser, comprising a semiconductor multi-layer structure in which a trench is formed, the trench running in a peripheral direction around a longitudinal center axis which runs perpendicularly to the semiconductor multi-layer structure and forming a mesa from the semiconductor multi-layer structure, the mesa containing a layer which is oxidized from an outer periphery of the mesa perpendicularly to the longitudinal center axis up to a predefined distance in order to form in the mesa an aperture for narrowing down an electrical and/or optical path.

### BACKGROUND

A semiconductor laser of this type is known from WO 2021/185697 A1.

Vertical-cavity surface-emitting semiconductor lasers, or VCSELs for short, are used, for example, as radiation sources in sensor technology or in communications engineering. VCSELs typically have a semiconductor multi-layer structure in which semiconductor layers are grown epitaxially on a semiconductor substrate in a stacked arrangement. A semiconductor multi-layer structure of this type can have a first Bragg reflector, an active region, and a second Bragg reflector, which together form an optical resonator. VCSELs typically also have an oxidized region in the optical resonator, which has a semiconductor layer that is oxidized up to a particular oxidation distance in order to form a current aperture and/or an optical aperture in the resonator, referred to in this description as an aperture. The semiconductor layer intended for oxidation is, for example, an Aluminum Arsenide (AIAs) layer that can be selectively oxidized to Aluminum Oxide (AI₂O₃₎ up to a particular oxidation distance. The predefined oxidation distance up to which said layer is oxidized is defined by the required aperture size and can be adjusted by the duration of the oxidation process. Prior to oxidation, a trench is made in the semiconductor multi-layer structure, for example by etching the semiconductor multi-layer structure from the upper face thereof. The trench typically has a depth of a few micrometers. The trench can be continuous or interrupted in the peripheral direction around the longitudinal center axis of the semiconductor multi-layer structure. The longitudinal center axis should be understood as the axis that passes through the center of the aperture and runs parallel to the stacking direction of the semiconductor multi-layer structure. The trench does not need to extend completely through the semiconductor multi-layer structure in the direction of the layer structure, but usually ends above the substrate. The trench forms a mesa in the semiconductor multi-layer structure, in which mesa the semiconductor layer to be oxidized is arranged. After the formation of the trench, the oxidation process can be carried out to oxidize the oxidizable layer, the oxidation starting from the outer periphery of the mesa and continuing until the aforementioned predefined oxidation distance is reached.

Traditionally, VCSEL trenches are produced with a geometry that is square, rectangular, or round.

A common problem with VCSELs is mechanical stress in the mesa, which can impair the functional reliability of the VCSEL, lead to VCSEL failure, or reduce the VCSEL's useful life. The mechanical stresses have various causes. One is that mechanical stresses are introduced into the mesa after oxidation to form the aperture, in particular when the oxidation distance is large. Another is that mechanical stresses can be induced in the mesa during the etching of the trench. Finally, the metallization on the upper face of the mesa for the electrical contacting of the VCSEL also contributes to mechanical stresses in the mesa.

The above-mentioned document WO 2021/185697 A1 proposes that, after oxidation of the oxidizable layer, the oxidized outer peripheral region be removed and an electrically non-conductive material be inserted into the resulting gap in order to reduce the mechanical stresses in the mesa caused by the oxidation layer. However, this does not address all the causes of mechanical stress in the mesa.

### SUMMARY

In an embodiment, the present disclosure provides a vertical-cavity surface-emitting semiconductor laser includes a semiconductor multi-layer structure in which a trench is formed, the trench running in a peripheral direction around a longitudinal center axis which runs perpendicularly to the semiconductor multi-layer structure and forming a mesa from the semiconductor multi-layer structure. The mesa contains a layer which is oxidized from an outer periphery of the mesa perpendicularly to the longitudinal center axis up to a predefined oxidation distance in order to form in the mesa an aperture for narrowing down an electrical and/or optical path. The trench has, in the peripheral direction around the longitudinal center axis, a plurality of portions in which the trench is closer to the longitudinal center axis than in other portions of the trench. The mesa has an inner mesa region and a plurality of support structures which surround the inner mesa region, the aperture is located in the inner mesa region, and the support structures are connected to the inner mesa region.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic top view of a vertical-cavity surface-emitting semiconductor laser (VCSEL);

FIG. 2 shows a section through the VCSEL in FIG. 1 along the line II-II in FIG. 1;

FIG. 3 shows a section through the VCSEL in FIG. 1 along a line III-III in FIG. 1;

FIG. 4 shows a schematic top view of another VCSEL;

FIG. 5 shows a schematic top view of another VCSEL;

FIG. 6 shows a schematic top view of another VCSEL;

FIG. 7 shows a schematic top view of another VCSEL;

FIG. 8 shows a schematic top view of another VCSEL;

FIG. 9 shows a schematic top view of another VCSEL;

FIG. 10 shows a schematic top view of another VCSEL; and

FIG. 11 shows a schematic top view of another VCSEL.

### DETAILED DESCRIPTION

The present disclosure provides a vertical-cavity surface-emitting semiconductor laser of the type mentioned above in which mechanical stresses in the mesa are further reduced or completely avoided.

The present disclosure includes a method for producing a VCSEL of the type described herein.

The VCSEL according to the present disclosure has a trench of which the geometry differs from the usual geometry of trenches of VCSELs. The trench of the VCSEL according to the present disclosure has, viewed in the peripheral direction around the longitudinal center axis, a plurality of portions in which the trench is closer to the longitudinal center axis of the mesa than in the other portions of the trench, the mesa thus having an inner mesa region and a plurality of support structures or an inner mesa region and a plurality of support structures which surround the inner mesa region. The aperture (current and/or optical narrowing) is located in the inner mesa region, and the support structures are connected to the inner mesa region. The inner mesa region and the support structures are formed from the semiconductor multi-layer structure. In other words, the trench is brought closer in portions to the center of the mesa, which is defined in this case by the aforementioned longitudinal center axis, and in portions the trench is moved further away from the center of the mesa in order to form support structures for the inner mesa region. This offers several advantages. Firstly, the oxidation distance is reduced because the dimensions of the inner mesa region perpendicularly to the longitudinal center axis are reduced in the portions in which the trench is brought closer to the longitudinal center axis. Another advantage is that the geometry of the trench according to the present disclosure creates support structures in the mesa that surround the inner mesa region and thus mechanically support it. Furthermore, the support structures can transfer mechanical stresses from the inner mesa region to the outside into the support structures, i.e., absorb them, so to speak. A further advantage is that one or more metallizations required for the electrical contacting of the VCSEL can be arranged on the support structures instead of on the inner mesa region, thereby also reducing or even avoiding mechanical stresses in the inner mesa region. Overall, the VCSEL according to the present disclosure therefore has the advantage that mechanical stresses in the inner mesa region, which is used to generate and emit light, are significantly reduced, thus significantly increasing the functional reliability and useful life of the VCSEL or significantly reducing its susceptibility to failure.

The aforementioned document WO 2021/185697 A1 describes support structures at a preliminary stage of the VCSEL during production thereof, but these are removed before the VCSEL is completed and are no longer present in the finished VCSEL. However, the VCSEL according to the present disclosure is a finished VCSEL in which the support structures are still present after its production.

Preferably, support structures of at least a subset of the support structures have, in all dimensions in a plane parallel to the semiconductor multi-layer structure or perpendicular to the longitudinal center axis, dimensions which are less than twice the oxidation distance of the oxidized layer.

An advantage here is that when the oxidizable layer of the semiconductor multi-layer structure is oxidized to form the aperture, this layer, which is also present in the support structures, is completely oxidized in the support structures. This makes these support structures particularly suitable for applying a metallization for electrical contacting of the VCSEL. The current flow from the relevant metallization then leads directly into the inner mesa region via the connection of this support to the inner mesa region, while short-circuit current paths from the metallization are avoided perpendicularly through the semiconductor layers of the support structure. The metallization can be limited to the upper face of the relevant support structure or partially extend, e.g., to an outer edge of the inner mesa region. Throughplating from the metallization via vias into the inner mesa region is also possible.

All support structures in the plane parallel to the semiconductor multi-layer structure can also be dimensioned such that they are smaller than twice the oxidation distance of the oxidized layer.

In an exemplary embodiment, the support structures comprise first support structures which, in all dimensions in a plane parallel to the semiconductor multi-layer structure, have dimensions which are less than twice the oxidation distance of the oxidized layer, and the support structures have second support structures which, at least in one dimension in a plane parallel to the semiconductor multi-layer structure, have a dimension which is greater than twice the oxidation distance of the partially oxidized layer.

In this embodiment, the trench thus forms at least two types of support structures. The combination of first and second support structures has the advantage that the "thinner" support structures can absorb stresses better because they are more flexible, while the second support structures, which are "thicker" and are not fully oxidized due to their larger dimensions, have higher mechanical stability. While the first support structures may have a metallization on their upper face because they are fully oxidized, the second support structures will not have a metallization because they are not fully oxidized. The first support structures and the second support structures can be arranged alternately around the inner mesa region.

As described above, it is advantageous if a region of the oxidized layer located within at least a subset of the support structures is completely oxidized.

Likewise, as already described above, it is advantageous if at least a subset of the support structures, preferably support structures in which the region of the oxidized layer is completely oxidized, has a surface metallization for electrical contacting of the semiconductor laser.

The metallization can be spatially limited to the relevant support or partially extend to the inner mesa region, e.g., to an edge thereof.

In the first case, if the metallization is spatially limited to the relevant support, the current flow from the metallization can be realized via the semiconductor connection of the support to the inner mesa region, or by means of throughplatings to a deeper layer having an

additional metallization layer. In the event that the metallization partially extends to the inner mesa region, a current flow from the metallization into the inner mesa region is ensured. The part of the metallization located on the inner mesa region can be significantly smaller in terms of its dimensions than the part of the metallization located on the support structure.

Preferably, at least four, at least six, or at least eight support structures are formed around the inner mesa region.

With a larger number of support structures, which can be dimensioned smaller in the plane parallel to the semiconductor multi-layer structure, mechanical stresses from the inner mesa region can be absorbed particularly well by the support structures. In particular, a larger number of support structures allows for better absorption of differently directed mechanical stresses, since the support structures can be arranged at smaller angular intervals around the inner mesa region with an increasing number of support structures.

Furthermore, it is preferred if the support structures form a support structure arrangement which is point-symmetrical with respect to the longitudinal center axis of the inner mesa region or mirror-symmetrical with respect to a plane parallel to the longitudinal center axis of the inner mesa region. Since the center of the inner mesa region is the location of greatest mechanical stresses, it is advantageous to choose a support structure arrangement that is point-symmetrical with respect to the center of the inner mesa region in order to direct the mechanical stresses radially symmetrically outward from the center of the inner mesa region.

Preferably, support structures of at least a subset of the support structures are designed as elongate connecting elements in the radial direction with respect to the longitudinal center axis, and/or support structures of at least a subset of the support structures are designed as columns.

Connecting elements have the advantage of being narrow and therefore more flexible in order to absorb stress. The connecting elements can also be described as suspension points for the inner mesa region. The connecting elements can be so narrow that the oxidizable layer within them is completely oxidized. In contrast, columns, which may have a rectangular, square, or round outer circumference, for example, have an improved mechanical support function for supporting the inner mesa region. Support structures designed as columns and support structures designed as connecting elements can be arranged in an alternating pattern around the inner mesa region.

An advantageous combination of connecting elements and columns consists in the fact that each column is connected to the inner mesa region via an elongate connecting element. In this embodiment, the advantages of a support structure in the form of a column (mechanical stability) and a support structure in the form of a connecting element (stress absorption) are combined.

It can be advantageous if each connecting element tapers toward or away from the inner mesa region.

This is advantageous if the connecting element has a width greater than twice the oxidation distance of the oxidized layer, such that full oxidation is ensured in the narrower tapered portion of the connecting element, thereby avoiding short-circuit current paths in the connecting element.

Furthermore, in an exemplary embodiment, the trench is wider in the region of the inner mesa region than in the region of the support structures.

This embodiment is particularly advantageous in the case where a large number of small or narrow support structures are to be formed through the trench. Widening the trench around the inner mesa region allows for more "free" standing support structures; in particular, a star-shaped geometry of the support structure arrangement can be created. In particular, if the support structures are formed from a combination of columns and connecting elements, the connecting elements can also be tapered, since such a support structure arrangement allows for good dissipation of mechanical stresses from the inner mesa region, but also ensures a smaller footprint for guiding the current in order to keep the capacitance of the inner mesa region low.

The widened trench can also serve as an improved heat sink close to the inner mesa region, for example by filling the trench with gold plating.

Furthermore, according to the present disclosure, a method for producing a vertical-cavity surface-emitting semiconductor laser is provided.

In the method according to the present disclosure, a trench having a geometry as described above with regard to the VCSEL according to the present disclosure is made in the semiconductor multi-layer structure, and, after the trench has been made, an oxidizable layer of the semiconductor multi-layer structure is oxidized in order to form in the inner mesa region the aperture for narrowing down an electrical and/or optical path in the inner mesa region.

The support structures created by the trench are either completely oxidized or only partially oxidized, as described above, depending on the dimensions of the support structures in a plane parallel to the semiconductor multi-layer structure.

The method according to the present disclosure has the same advantages as the VCSEL according to the present disclosure.

The trench can be made in the semiconductor multi-layer structure by any suitable etching process known in the field of VCSEL production.

In the context of the present disclosure, a "trench" is understood to be a trench which is bounded on both sides by a wall made of the semiconductor multi-layer structure or only by a wall, in the latter case by the outer wall of the mesa.

Further advantages and features can be found in the following description and the attached drawings.

It should be understood that the features mentioned above and those to be explained below can be used not only in the combination specified in each case, but also in other combinations or on their own without departing from the scope of the present disclosure.

Exemplary embodiments of the present disclosure are shown in the drawing and are described in more detail below with reference thereto.

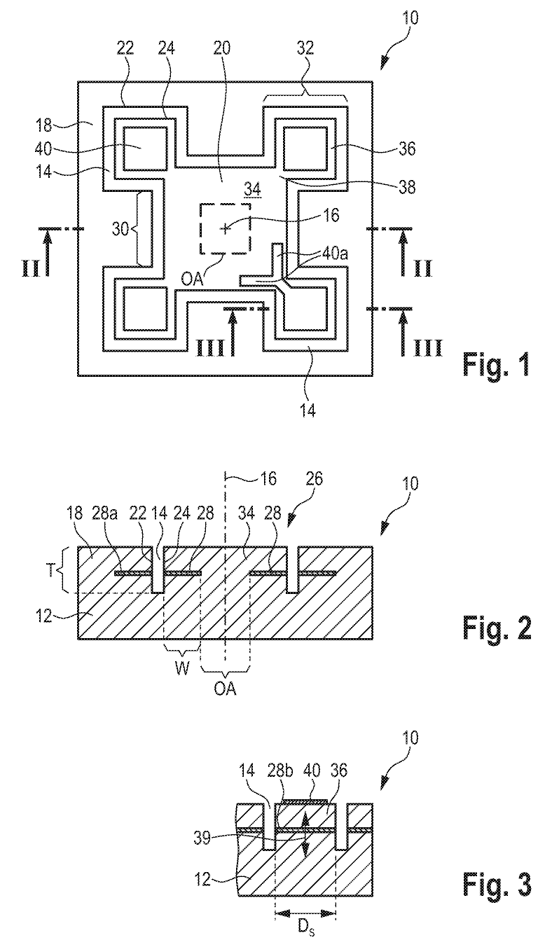

FIGS. 1 to 11 show different embodiments of a vertical-cavity surface-emitting semiconductor laser (VCSEL). It should be understood that the VCSELs shown and their structural features are not to scale.

FIGS. 1 to 3 show a first VCSEL 10. The VCSEL 10 has a semiconductor multi-layer structure 12. The semiconductor multi-layer structure can be constructed in the manner typical for VCSELs. Details of the semiconductor multi-layer structure 12 are not relevant for understanding the present disclosure and are therefore not described here. For example, the semiconductor multi-layer structure 12 can be arranged on a substrate. Starting from the substrate, the semiconductor multi-layer structure 12 can have a first Bragg reflector, an active zone, and a second Bragg reflector, as well as an electrical contact for applying a drive current to the VCSEL.

In the semiconductor multi-layer structure 12, a trench 14 is formed which runs in a peripheral direction around a longitudinal center axis 16 of the semiconductor multi-layer structure 12. The longitudinal center axis 16 is understood to be an axis that runs centrally through the semiconductor multi-layer structure 12 or the VCSEL 10 perpendicularly to the individual layers of the semiconductor multi-layer structure 12. In other words, the longitudinal center axis 16 runs in the stacking direction of the individual semiconductor layers of the semiconductor multi-layer structure 12.

In the embodiment shown inFIGS. 1 to 3 and the further drawings, the trench 14 is shown as a trench formed continuously around the longitudinal center axis 16. However, the trench 14 may also have interruptions in the peripheral direction around the longitudinal center axis.

Typically, the trench 14 has a depth T of a few micrometers. In the embodiment in FIGS. 1 to 3, the trench 14 separates a first (outer) region from a second (inner) region 20. In this embodiment, the trench 14 thus has a first (outer) wall 22 and a second (inner) wall 24. It should be understood that the trench 14 can only be bounded on one side by a wall, namely the wall 24, such that, in other words, the first region 18 of the semiconductor multi-layer structure 12 is missing.

The trench 14 may have been made by means of an etching process commonly used in the production of VCSELs. The second (inner) region 20 of the semiconductor multi-layer structure is formed as a mesa 26 on account of the trench.

In the mesa 26, a layer 28 is arranged which is oxidized from the outer periphery of the mesa 26, i.e., the wall 24, perpendicularly to the longitudinal center axis 16 up to a predefined oxidation distance W in order to form in the mesa 26 an aperture OA for narrowing down an electrical and/or optical path. Before oxidation, the layer 28 is a layer of the semiconductor multi-layer structure 12 that is easily oxidized, for example an AIAs layer. After the trench 14 was made, the semiconductor multi-layer structure 12 was exposed to an oxidation atmosphere which oxidized the layer 28 from the wall 24 up to the predefined oxidation distance W. The oxidation distance W is determined by the duration of the oxidation process. The central region of the layer 28 remains unoxidized and defines the aperture OA. Since, in the illustrated embodiment, the layer 28 extends into the first region 18, the layer 28 is also oxidized in the first region 18 up to the oxidation distance, as indicated by a portion 28a.

The trench 14 has a plurality of portions 30 in the peripheral direction around the longitudinal center axis 16, the trench 14 in FIG. 1 having a total of four such portions 30 in which the trench 14 is arranged closer to the longitudinal center axis 16 than in other portions 32. Due to this geometry of the trench 14, an inner mesa region 34 is formed in the mesa 26 within the trench, and a plurality of support structures 36 surround the inner mesa region 34. In the illustrated embodiment, four support structures 36 are formed. The aperture OA is located in the inner mesa region 34. The support structures 36 are connected to the inner mesa region 34 via narrow connecting portions 38. The support structures 36 together with the connecting portions 38 are formed from the same semiconductor multi-layer structure 12 as the inner mesa region 34. Due to the portions 30 of the trench 14, which are brought closer to the longitudinal center axis 16, the oxidation path for producing the aperture OA is advantageously reduced compared to conventional VCSELs, which not only makes the oxidation process shorter in terms of time, but also reduces mechanical stresses in the inner mesa region 34 due to the shorter oxidation length or reduced oxidation distance W. Furthermore, the shape of the aperture OA can be designed as desired via the geometry of the portions 30 of the trench 14 that are closer to the longitudinal center axis 16. In FIG. 1, the four portions 30 together substantially form the shape of a square, and therefore the aperture OA is also square.

A desired geometry of the trench 14 can be defined by a suitably designed etching mask when etching the trench 14.

The support structures 36 increase the mechanical stability of the inner mesa region 34. The support structures 36 can also transfer mechanical stresses from the inner mesa region 34 into the support structures 36. The support structures 36 can be described as extensions of the inner mesa region 34.

In the embodiment according FIGs. 1 to 3, the support points have, in all dimensions in a plane parallel to the layers of the semiconductor multi-layer structure 12 (FIG. 3), dimensions D_{S} which are less than twice the oxidation distance W of the oxidized layer 28. In the embodiment shown in FIGs. 1 to 3, the support points 36 are approximately square in shape. The four side lengths of the support structures 36 are therefore less than or equal to twice the oxidation distance W. This causes the support structures 36 to be completely oxidized during the oxidation process for producing the aperture OA, as shown in FIG. 3 with the portion 28b of the layer 28 in the support structure 36. Due to the complete oxidation of the layer 28 in the support structures, no current flow through the support structures 36 is possible in the direction of a double arrow 39 in FIG. 3. This can, in turn, be advantageously used to provide the support structures 36 on their upper face with a metallization 40, which is used for the electrical contacting of the VCSEL 10. For example, the metallization 40 is used to create a p-contact of the VCSEL. Preferably, a metallization 40 is provided on each of the support structures 36. A current can flow from the metallizations 40 on the support structures 36 via the connecting portions 38 into the inner mesa region 34 and from there through the aperture OA. The metallizations 40 can be limited to the support structures 36, or, as shown in Fig. 1 with a metallization extension 40a, they can extend to the edge region of the inner mesa region 34.

If the metallizations 40 do not extend into the inner mesa region 34, this has the advantage of a mechanical decoupling of the metallizations 40 from the inner mesa region 34, thereby further reducing mechanical stresses in the inner mesa region 34 due to metallizations. If the metallizations 40 are limited to the support structures 36, these can be connected to the inner mesa region 34 via a single throughplating using vias and an additional metallization.

In a method for producing the VCSEL 10, the trench 14 with the geometry described above is made in the semiconductor multi-layer structure 12. The trench is made in the semiconductor multi-layer structure 12 by means of a suitable etching process using an etching mask which is designed according to the geometry of the trench 14 to be created. After the trench 14 has been made, the layer 28 of the semiconductor multi-layer structure is oxidized in order to form in the inner mesa region 34 the aperture OA for narrowing down an electrical and/or optical path in the inner mesa region 34. The layer 28 in the support structures 36 is completely oxidized. The metallizations 40 are applied to the support structures 36.

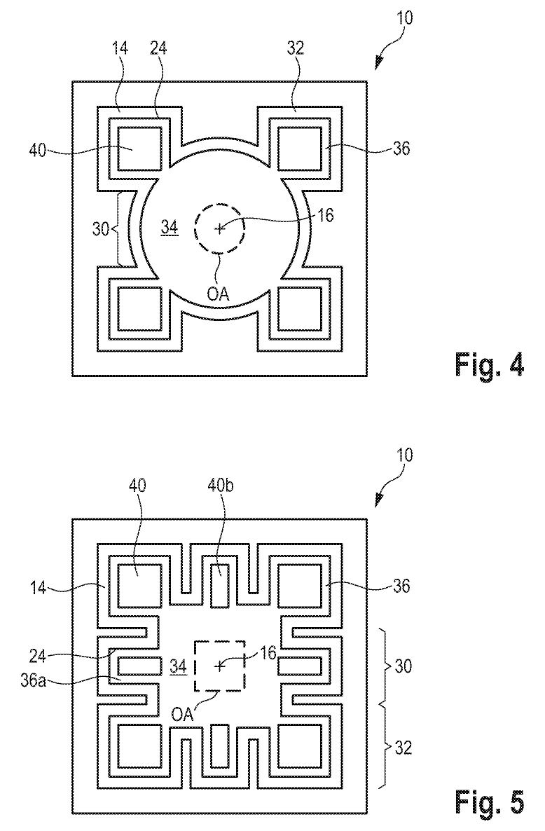

Further embodiments of a VCSEL are described in each case with reference to FIGs. 4 to 11. Only the differences compared to the VCSEL 10 in FIGs. 1 to 3 are described. Furthermore, reference is made to the description of the embodiment of the VCSEL 10 in FIGs. 1 to 3. Furthermore, the same reference signs as in FIGs. 1 to 3 are used in FIGs. 4 to 11, insofar as they denote identical, similar, or comparable elements of the VCSELs 10 in FIGs. 4 to 11.

In the VCSEL 10 in FIG. 4, the portions 30 of the trench 14, which are arranged closer to the longitudinal center axis 16 than the portions 32 of the trench 14, are in the shape of a partial circle. This makes the inner mesa region 34 circular, as well as the aperture OA. As mentioned above, the geometry of the portions 30 can determine not only the shape of the inner mesa region 34, but also the shape of the aperture OA.

In the embodiment in FIG. 4, the portions 30 of the trench 14, which are brought closer to the longitudinal center axis 16 than the other regions 32 of the trench 14, have a meandering shape, thereby forming additional support structures 36a in addition to the support structures 36. The support structures 36a in turn have dimensions in all dimensions in a plane parallel to the semiconductor multi-layer structure 12 which are less than twice the oxidation distance W of the layer 28 (as described above with reference to Fig. 1). This makes it possible to also provide the additional support structures 36a with metallizations 40b on their upper face, since the additional support structures 36a, like the support structures 36, do not form short-circuit current paths through them.

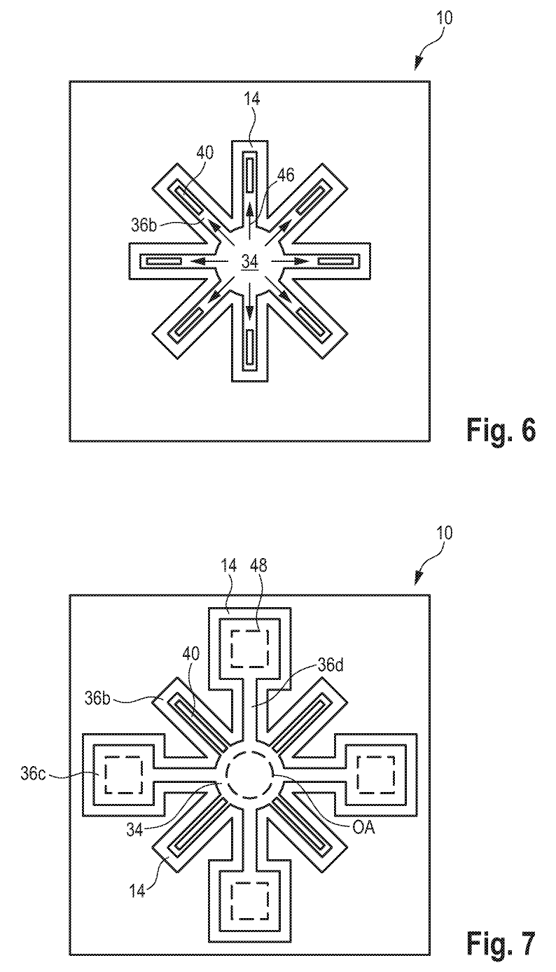

While the embodiments in FIGs. 1 to 4 have a total of four support structures 36, the embodiment in FIG. 5 has a total of eight support structures 36, 36a. The support structures 36 in FIGs. 1 to 4 each form a support structure arrangement that is both point-symmetrical with respect to the longitudinal center axis 16 and mirror-symmetrical with respect to a plane containing the longitudinal center axis 16. The support structures 36, 36a of the VCSEL 10 in FIG. 5 also form a point or mirror-symmetrical arrangement of support structures, as do the embodiments in FIGs. 6 to 11 to be described below.

FIG. 6, shows an embodiment of a VCSEL 10 in which the trench 14 has a geometry that forms an inner mesa region 34 and support structures 36b in the semiconductor multi-layer structure 12, the support structures 36b being designed as elongate connecting elements. In FIG. 6, the aperture OA is not shown, but it is also present in the inner mesa region 34 as in the previous embodiments. In FIG. 6, the inner mesa region 34 is circular like in FIG. 4, as is the aperture OA (not shown). The support structures 36b from the semiconductor multi-layer structure 12 have such dimensions that the layer 28 in the support structures 36b is completely oxidized. Accordingly, the support structures 36b can be provided with metallizations 40 for electrical contacting of the VCSEL 10. The embodiment in FIG. 6 is advantageous with respect to the symmetry of the support structures 36b around the center of the inner mesa region 34, since mechanical stresses from the inner mesa region 34 are transferred radially symmetrically into the support structures 36b, as illustrated by arrows 46. Due to the geometry of the support structures 36b as elongate connecting elements, they are particularly suitable for absorbing stresses.

FIG. 7 shows an embodiment of a VCSEL 10, which is a variation of the embodiment shown in Fig. 6. In the embodiment of the VCSEL 10 in Fig. 7, the trench 14 forms two types of support structures. Firstly, the support structures 36b as shown in FIG. 6, which bear metallizations 40 on their upper face. Furthermore, support structures 36c are formed which, similar to the embodiments in FIGs. 1 to 5, are designed as columns, but which, unlike the support structures 36 in FIGs. 1 to 5, have a dimension in at least one dimension parallel to the plane of the semiconductor multi-layer structure 12 which is greater than twice the oxidation distance W, and therefore the layer 28 is not completely oxidized in the support structures 36c in the form of columns, as indicated by dashed lines 48. This is innocuous with regard to a current path through the support structures 36c that is possible in principle, since the support structures 36c do not have any metallization on their upper face and are therefore not used for contacting the VCSEL 10. The support structures 36c in the form of columns are connected to the inner mesa region 34 by support structures 36d in the form of connecting elements, which in turn are so narrow that the layer 28 of the semiconductor multi-layer structure 12 is completely oxidized in these support structures 36d in the form of connecting elements. The advantage of the larger support structures 36c in the form of columns is their greater mechanical stability, i.e., they act as support columns, so to speak, in the outer region of the mesa 26.

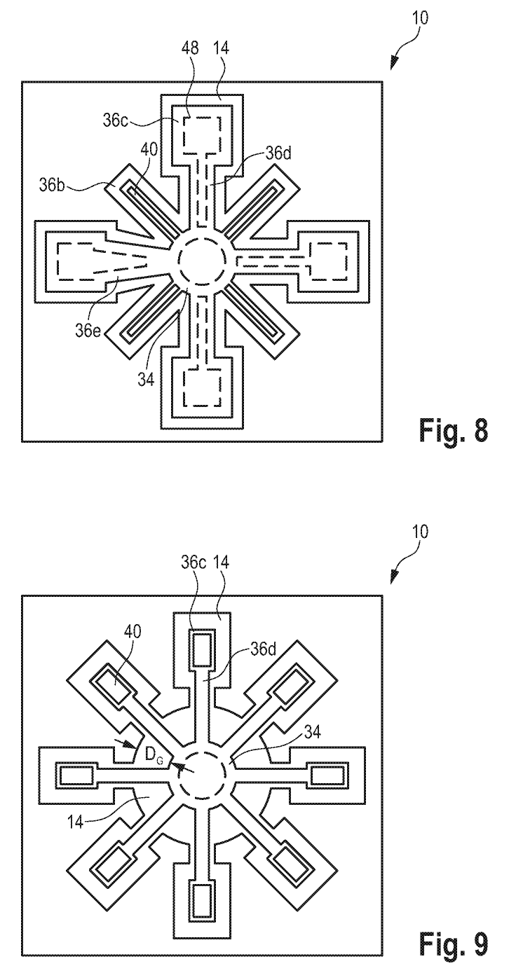

Fig. 8 shows a variation of the VCSEL 10 in Fig. 7, according to which the support structures 36d in the form of connecting elements, which connect the support structures 36c in the form of columns to the inner mesa region 34, are widened, such that the support structures 36d also have a higher mechanical stability. Due to the widening of the support structures 36d by more than twice the oxidation distance W, the layer 28 in the region of the support structures 36d is not fully oxidized, as indicated by dashed lines. However, this is innocuous, since the support structures 36c and 36d do not have any metallization on their upper face.

Furthermore, it is possible for the support structures in the form of connecting elements connecting the support structures 36c in the form of columns to the inner mesa region 34 to widen from the inner mesa region 34 to the support structures 36c in the form of columns, as shown by a support structure 36e in the form of a connecting element in FIG. 8. The advantage here is that, in addition to increased mechanical stability due to a greater connecting element width of the support structure 36e, full oxidation and the layer 28 in the support structure 36e and thus insulation is made possible. The embodiment in Fig. 8 is characterized by a very small oxidation distance, a low ohmic resistance due to metallizations 40 brought close to the inner mesa region 34 on the support structures 36b, and a high mechanical stability due to additional support structures 36c in the form of columns.

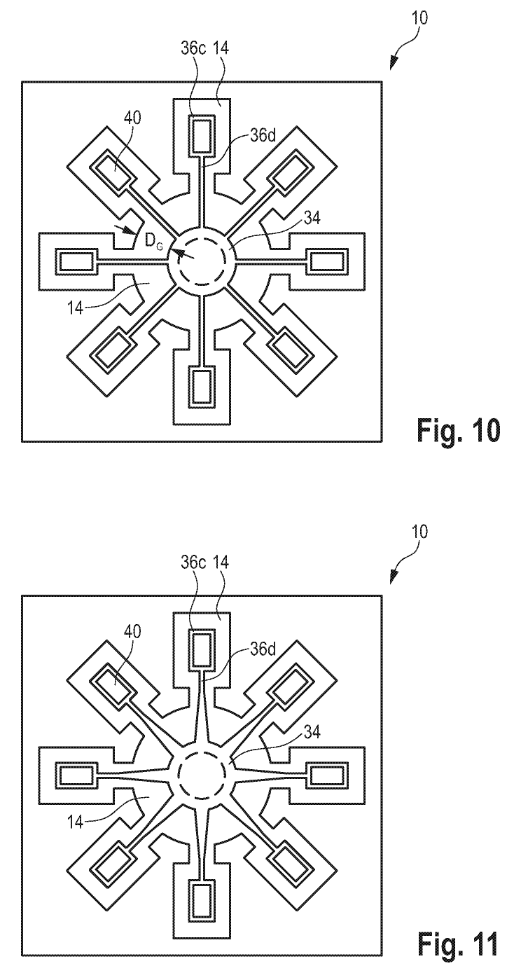

FIGs. 9 to 11 show further embodiments of VCSELs 10, which have in common the fact that the trench 14 in the region of the inner mesa region 34 has, in a plane parallel to the layers of the semiconductor multi-layer structure 12 or perpendicular to the longitudinal center axis 16, a width D_{G} which is greater than the width of the relevant trench 14 in FIGs. 1 to 8. In the embodiments in FIGS. 9 to 11, the trench 14 is further designed such that narrower and longer support structures 36d in the form of connecting elements are formed, which can correspondingly dissipate more stress from the inner mesa region 34. Due to the small dimensions of the support structures 36d in the form of connecting elements and of the support structures 36c in the form of columns, the layer 28 in these support structures can be completely oxidized, such that all support structures 36c in the form of columns, and possibly also the support structures 36d, can be provided with metallizations 40 on their upper face. In the embodiment in FIG. 10, the support structures 36d in the form of connecting elements are even narrower than in the embodiment inFIG. 9. In the embodiment in FIG. 11, the support structures 36d in the form of connecting elements taper toward the support structures 36c in the form of columns, thereby ensuring, as in the embodiment inFIG. 10, good dissipation of stresses from the inner mesa region 34 and also allowing for a smaller footprint for current conduction, such that no excessively large mesa capacitance is generated. The embodiment in Fig. 11 resembles a star-shaped geometry of the inner mesa region 34 together with the support structures 36d and 36c.

Additionally, in the embodiments in FIGS. 9 to 11, the trench can be filled with a gold plating, thereby increasing the metal heat sink close to the inner mesa region 34.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A vertical-cavity surface-emitting semiconductor laser, comprising:
a semiconductor multi-layer structure in which a trench is formed, the trench running in a peripheral direction around a longitudinal center axis which runs perpendicularly to the semiconductor multi-layer structure and forming a mesa from the semiconductor multi-layer structure, the mesa containing a layer which is oxidized from an outer periphery of the mesa perpendicularly to the longitudinal center axis up to a predefined oxidation distance in order to form in the mesa an aperture for narrowing down an electrical and/or optical path,
wherein the trench has, in the peripheral direction around the longitudinal center axis, a plurality of portions in which the trench is closer to the longitudinal center axis than in other portions of the trench,
wherein the mesa has an inner mesa region and a plurality of support structures which surround the inner mesa region, and
wherein the aperture is located in the inner mesa region and the support structures are connected to the inner mesa region.

2. The vertical-cavity surface-emitting semiconductor laser according to claim 1, wherein at least a subset of the support structures have, in all dimensions in a plane parallel to the semiconductor multi-layer structure, dimensions which are less than twice the predefined oxidation distance of the oxidized layer.

3. The vertical-cavity surface-emitting semiconductor laser according to claim 2, wherein the support structures comprise first support structures which, in all dimensions in the plane parallel to the semiconductor multi-layer structure, have dimensions which are less than twice the predefined oxidation distance of the oxidized layer, and wherein the support structures have second support structures which, at least in one dimension in the plane parallel to the semiconductor multi-layer structure, have a dimension which is greater than twice the predefined oxidation distance of the oxidized layer.

4. The vertical-cavity surface-emitting semiconductor laser according to claim 1, wherein a portion of the oxidized layer located within at least a subset of the support structures is completely oxidized.

5. The vertical-cavity surface-emitting semiconductor laser according to claim 1, wherein at least a subset of the support structures have a surface metallization for electrical contacting of the semiconductor laser.

6. The vertical-cavity surface-emitting semiconductor laser according to claim 5, wherein the surface metallization is spatially limited to a relevant support structure or partially extends to the inner mesa region.

7. The vertical-cavity surface-emitting semiconductor laser according to claim 1, wherein at least four, at least six, or at least eight support structures of the support structures are formed which are distributed around the inner mesa region.

8. The vertical-cavity surface-emitting semiconductor laser according to claim 1, wherein the support structures form a support structure arrangement which is point-symmetrical with respect to the longitudinal center axis or mirror-symmetrical with respect to a plane parallel to the longitudinal center axis.

9. The vertical-cavity surface-emitting semiconductor laser according to claim 1, wherein at least a subset of the support structures are designed as elongate connecting elements in a radial direction with respect to the longitudinal center axis.

10. The vertical-cavity surface-emitting semiconductor laser according to claim 1, wherein at least a subset of the support structures are designed as columns.

11. The vertical-cavity surface-emitting semiconductor laser according to claim 10, wherein each column is connected to the inner mesa region via an elongate connecting element, wherein, in a plane perpendicular to the longitudinal center axis, the column has dimensions which are greater than a width of the connecting element.

12. The vertical-cavity surface-emitting semiconductor laser according to claim 11, wherein each connecting element tapers toward or away from the inner mesa region.

13. The vertical-cavity surface-emitting semiconductor laser according to claim 1, wherein the trench is widened in the region of the inner mesa region.

14. A method for producing a vertical-cavity surface-emitting semiconductor laser, comprising the steps of:
providing a semiconductor multi-layer structure,
making a trench in the semiconductor multi-layer structure, wherein the trench runs in a peripheral direction around a longitudinal center axis which runs perpendicularly to the semiconductor multi-layer structure and forms a mesa from the semiconductor multi-layer structure, wherein the trench has, in the peripheral direction around the longitudinal center axis, a plurality of portions in which the trench is closer to the longitudinal center axis than in other portions of the trench, wherein the mesa has an inner mesa region and a plurality of support structures which surround the inner mesa region, and wherein the support structures are connected to the inner mesa region,
oxidizing an oxidizable layer of the semiconductor multi-layer structure in order to form in the inner mesa region an aperture for narrowing down an electrical and/or optical path.
